(19) United States
(12) Patent Application Publication
(10) Pub. No.: US 2019/0331432 A1
(43) Pub. Date: Oct. 31, 2019

(54) LOOP HEAT PIPE HAVING CONDENSATION SEGMENT PARTIALLY FILLED WITH WICK

(71) Applicant: TAI-SOL ELECTRONICS CO., LTD., Taipei City (TW)

(72) Inventors: Chuan-Chi TSENG, TAIPEI CITY (TW); Yueh-Lung CHUANG, TAIPEI CITY (TW); Xiao-Long WU, WUJIANG CITY (CN)

(21) Appl. No.: 16/034,838

(22) Filed: Jul. 13, 2018

(30) Foreign Application Priority Data
Apr. 26, 2018 (TW) 107114331

(51) Int. Cl. F28D 15/04; B33Y 10/00; F28D 15/02; H05K 7/20

(52) U.S. Cl. CPC F28D 15/046; H05K 7/20336; F28D 15/0275; B33Y 10/00

(57) ABSTRACT

A loop heat pipe having a condensation segment partially filled with a wick, including: an evaporation chamber having a casing and a first wick disposed therein, the casing being not fully filled with the first wick such that a first space is formed therebetween; a condensation segment being a hollow-cored tube partially filled with the second wick and having a vapor connection end and a liquid connection end communicating with the vapor connection end, the tube having therein a second wick corresponding in position to the liquid connection end and a second space corresponding in position to the vapor connection end; a vapor delivery pipe having an end communicating with the first space and another end communicating with the second space; and a liquid delivery pipe filled with a third wick and having an end communicating with the casing and another end communicating with the condensation segment.

### BACKGROUND OF THE INVENTION

### 1. Technical Field

The present disclosure relates to heat-dissipating devices and, more particularly, to a loop heat pipe having a condensation segment partially filled with a wick.

### 2. Description of Related Art

Electronic devices are widely used in modern daily life. Due to increasingly advanced technology, plenty of electronic devices must be heavily powered in order to operate; as a result, they generate heat which increases their temperature, damages their structure, and lowers their performance.

In recent years, there is developed a heat pipe which works by the principle of heat transfer and uses a refrigerating medium capable of quick heat transfer to transfer heat from an electronic device to its surroundings quickly. The heat pipe is succeeded by a loop heat pipe. The loop heat pipe includes a heat-dissipating device, a condensation device, a gaseous pipeline and a liquid pipeline. The gaseous pipeline and the liquid pipeline are connected between the heat-dissipating device and the condensation device. The loop heat pipe is filled with a working fluid. Heat generated from an electronic device is transferred from the heat-dissipating device to the working fluid. After absorbing the heat, the working fluid evaporates into a gaseous working fluid. The gaseous working fluid is delivered by the gaseous pipeline to a condenser where heat dissipation, cooling, and condensation take place, turning the gaseous working fluid into a liquid working fluid. Then, the liquid working fluid is delivered by the liquid pipeline to the heat-dissipating device where the liquid working fluid absorbs heat from the surface of the heat-dissipating device again. Therefore, the electronic device is cooled down by the working fluid which alternates between evaporation (absorption of heat) and condensation (release of heat).

The loop heat pipe is disclosed in Taiwan's published patent application 200815725, entitled Loop Heat Pipe, and is described below. The liquid pipeline has therein a flexible woven duct. A woven wall of the duct forms a capillary structure capable of generating a capillary force under which a working fluid moves toward an evaporation portion. However, the flexible woven duct is disposed on a sidewall of a condensation portion (i.e., inside the pipe) and does not fully occupy the interior of the condensation portion and a liquid delivery channel. The working fluid is evaporated by the evaporation portion into a gaseous working fluid. The gaseous working fluid is delivered by the gaseous pipeline to the condensation portion. The gaseous working fluid in the condensation portion condenses into a liquid working fluid. The liquid working fluid in the condensation portion freezes and attaches to the inner wall thereof and thus cannot adsorb to the capillary structure of the duct. As a result, the return of the liquid working fluid to the evaporation portion is slow and thus inefficient.

The aforesaid issue is addressed by Taiwan's published patent application 200815725. Referring to its FIG. 1, the working fluid is voluminous enough to ensure that both a liquid delivery segment and the condensation portion are nearly fully filled with the liquid working fluid. However, this greatly reduces a condensation segment's space which the gaseous working fluid may enter. As a result, the space for and extent of phase transition of the gaseous working fluid is reduced to the detriment of heat dissipation efficiency.

### BRIEF SUMMARY OF THE INVENTION

It is an objective of the present disclosure to provide a loop heat pipe having a condensation segment partially filled with a wick and thus dispensing with the need to contain a large amount of a working fluid. Therefore, a liquid working fluid can adsorb to the wick efficiently and return to an evaporation chamber quickly, so as to enhance heat dissipation efficiency.

In order to achieve the above and other objectives, the present disclosure provides a loop heat pipe having a condensation segment partially filled with a wick, comprising: an evaporation chamber having a casing and a first wick disposed in the casing, the casing being not fully filled with the first wick such that a first space is formed between the casing and the first wick; a condensation segment being a hollow-cored tube, the hollow-cored tube having a vapor connection end and a liquid connection end in communication with the vapor connection end, the tube being externally provided with a heat-dissipating unit, the tube being partially filled with a second wick to form a second space in the tube, the second wick being disposed at the liquid connection end of the tube, wherein the second space has an end adjoining the second wick and another end being in communication with the vapor connection end; a vapor delivery pipe having an end not only connecting to the casing but also being in communication with the first space and another end not only connecting to the vapor connection end of the condensation segment but also being in communication with the second space; and a liquid delivery pipe having an end not only connecting to the casing but also being in communication with the casing and another end not only connecting to the liquid connection end of the condensation segment but also being in communication with the condensation segment, wherein the liquid delivery pipe is filled with a third wick, the third wick being in contact with the first wick and the second wick.

The condensation segment has therein the second space and the second wick which the condensation segment is partially filled with, and thus the gaseous working fluid can accumulate in the second space. Furthermore, under a capillary force provided by the second wick, the liquid working fluid resulting from condensation can return to the evaporation chamber quickly and thus begin the next instance of circulation, so as to enhance heat dissipation efficiency.

### BRIEF DESCRIPTION OF THE SEVERAL VIEWS OF THE DRAWINGS

FIG. 1 is a perspective view of a loop heat pipe according to the first preferred embodiment of the present disclosure;

FIG. 2 is a cutaway view of the loop heat pipe of FIG. 1;

FIG. 3 is a cutaway view of the loop heat pipe according to another aspect of the first preferred embodiment of the present disclosure;

FIG. 4 is a cutaway view of a loop heat pipe according to the second preferred embodiment of the present disclosure;

FIG. 5 is a schematic view of the loop heat pipe of FIG. 4;

FIG. 6 is a cutaway view of the loop heat pipe according to another aspect of the second preferred embodiment of the present disclosure;

FIG. 7 is a cutaway view of the loop heat pipe according to the third preferred embodiment of the present disclosure;

FIG. 8 is a cutaway view of the loop heat pipe according to the fourth preferred embodiment of the present disclosure; and

FIG. 9 is a cross-sectional view of the loop heat pipe according to the fifth preferred embodiment of the present disclosure.

### DETAILED DESCRIPTION OF THE INVENTION

Structures and features of the present disclosure are hereunder illustrated with preferred embodiments, depicted by the accompanying drawings, and described in detail below.

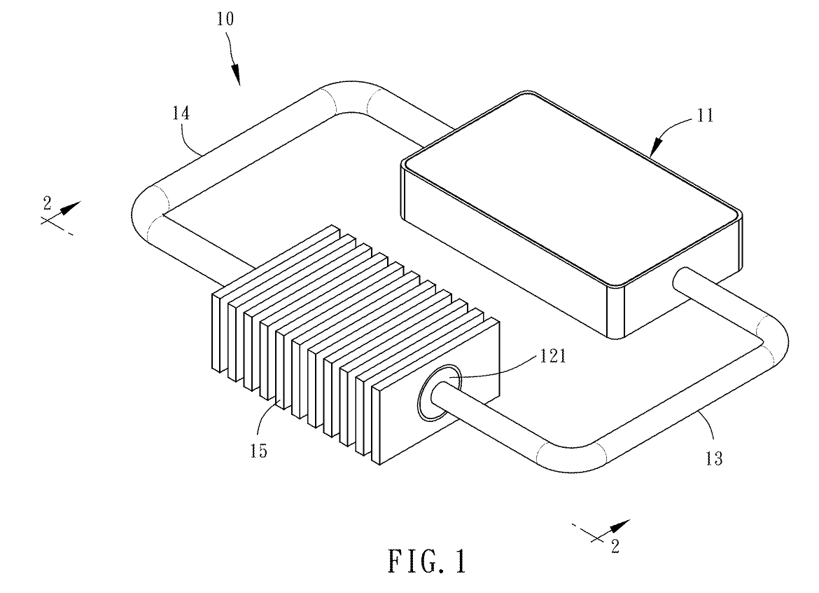

As shown in FIG. 1 through FIG. 3, the first preferred embodiment of the present disclosure provides a loop heat pipe 10 having a condensation segment partially filled with a wick. The loop heat pipe 10 essentially comprises an evaporation chamber 11, a condensation segment 12, a vapor delivery pipe 13 and a liquid delivery pipe 14.

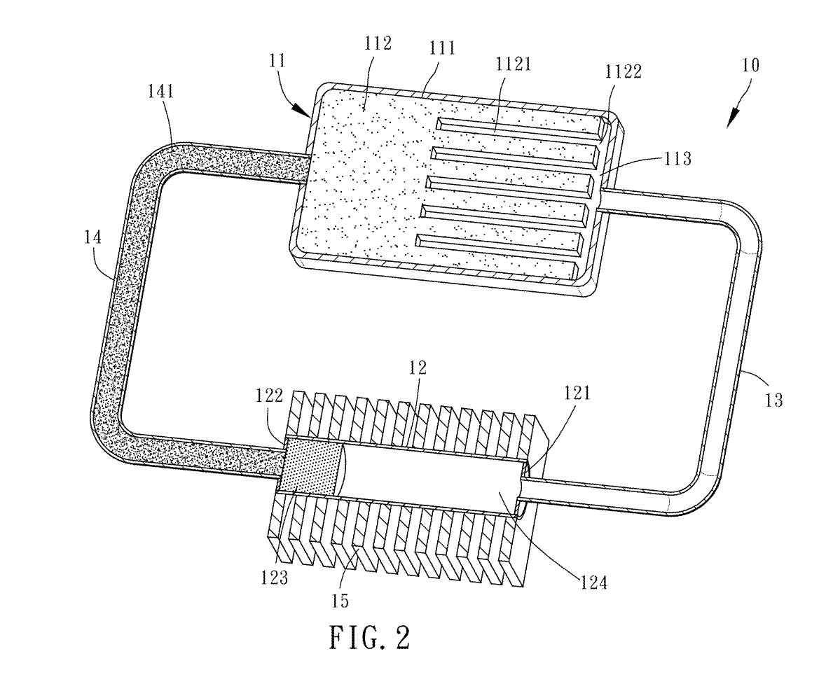

The evaporation chamber 11 has a casing 111 and a first wick 112 disposed in the casing 111. As shown in FIG. 1 and FIG. 2, the casing 111 is a six-sided container, whereas the first wick 112 is a six-sided solid of a smaller length than the casing 111. The casing 111 is not fully filled with the first wick 112; hence, a first space 113 is formed between the casing 111 and the first wick 112. The casing 111 contains a working fluid (not shown, because the working fluid flows within the first wick 112). The first wick 112 is a capillary structure made from sintered powder, mesh or fiber. The first wick 112 has a plurality of channels 1121 (well known among persons skilled in the art and thus, for the sake of brevity, not described herein). Channel openings 1122 of the channels 1121 correspond in position to the first space 113.

The condensation segment 12 is a hollow-cored tube which has a vapor connection end 121 and a liquid connection end 122 in communication with the vapor connection end 121. The tube is externally provided with a heat-dissipating unit 15 (of a variable shape and structure; for example, the heat-dissipating unit 15 is a plurality of cooling fins fitted around the condensation segment 12; in this regard, the heat-dissipating unit 15 is well known among persons skilled in the art and thus, for the sake of brevity, is not described herein) to dissipate heat and perform a cooling function. The tube is partially filled with a second wick 123 to form a second space 124 in the tube. The second wick 123 is a capillary structure made from sintered powder, mesh or fiber. As shown in the diagrams which illustrate this embodiment, the second wick 123 looks like a short post disposed in the condensation segment 12 and corresponding in position to the liquid connection end 122 of the tube. One end of the second space 124 is in contact with the second wick 123. The other end of the second space 124 is in communication with the vapor connection end 121.

One end of the vapor delivery pipe 13 connects to the casing 111 and is in communication with the first space 113. The other end of the vapor delivery pipe 13 connects to the vapor connection end 121 of the condensation segment 12 and is in communication with the second space 124.

In the first preferred embodiment of the present disclosure, the liquid delivery pipe 14 is of a larger inner diameter than the vapor delivery pipe 13. One end of the liquid delivery pipe 14 connects to the casing 111 and is in communication with the interior of the casing 111. The other end of the liquid delivery pipe 14 connects to the liquid connection end 122 of the condensation segment 12 and is in communication with the interior of the condensation segment 12. The liquid delivery pipe 14 is filled with a third wick 141. The third wick 141 is a capillary structure made from sintered powder, mesh or fiber and is in contact with the first wick 112 and the second wick 123.

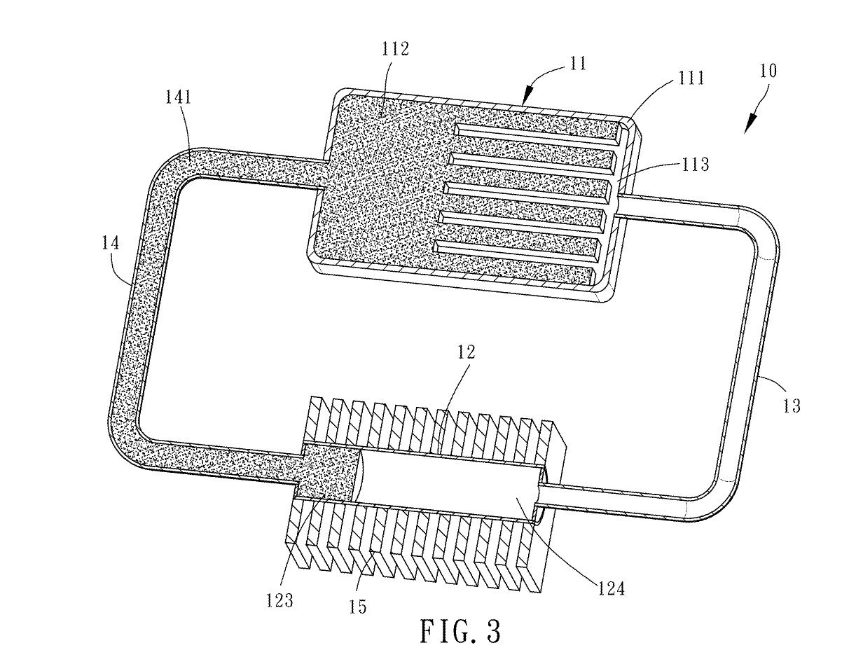

As shown in FIG. 2, the first wick 112, the second wick 123 and the third wick 141 are separate, self-contained capillary structures placed in the casing 111, the condensation segment 12 and the liquid delivery pipe 14, respectively. Alternatively, as shown in FIG. 3, the first wick 112, the second wick 123 and the third wick 141 are integrally formed by sintering and simultaneously placed in the casing 111, the condensation segment 12 and the liquid delivery pipe 14.

Given the aforesaid structure, before using the loop heat pipe 10, a user places a heat source, such as an electronic device, on the evaporation chamber 11. After operating for a time period, the heat source (not shown) begins to generate heat. The heat thus generated is transferred, by conduction, from the heat source to the evaporation chamber 11 and then to the first wick 112. The working fluid is stored in the first wick 112 mostly in liquid form. As soon as heat is taken up by the first wick 112, the temperature of the first wick 112 rises such that a liquid working fluid stored in the first wick 112 takes up sufficient heat and thus gradually evaporates into a gaseous working fluid. The gaseous working fluid moves out of the channel openings 1122 of the channels 1121 of the first wick 112 so as to reach and accumulate in the first space 113; afterward, the gaseous working fluid moves to the condensation segment 12 via the vapor delivery pipe 13. As soon as the gaseous working fluid reaches the condensation segment 12 via the vapor delivery pipe 13, the heat-dissipating unit 15 provided externally for the condensation segment 12 condenses the gaseous working fluid passing the condensation segment 12 into a liquid working fluid. The condensation segment 12 not only has the second space 124 but is also partially filled with the second wick 123; hence, the liquid working fluid accumulates in the second space 124.

Afterward, the liquid working fluid comes into contact with the third wick 141 in the liquid delivery pipe 14 through the second wick 123 in the condensation segment 12 such that under a capillary force the liquid working fluid proceeds with its flow toward the liquid delivery pipe 14 and returns to the evaporation chamber 11 to repeat the aforesaid steps, thereby enhancing the heat dissipation efficiency of the loop heat pipe of the present disclosure.

Therefore, according to the present disclosure, since the condensation segment 12 is just partially filled with the second wick 123, not only can the liquid working fluid be adsorbed to the second wick 123, but the liquid working fluid can also return to the evaporation chamber 11 quickly because of the third wick 141, thereby enhancing the heat dissipation efficiency of the loop heat pipe 10.

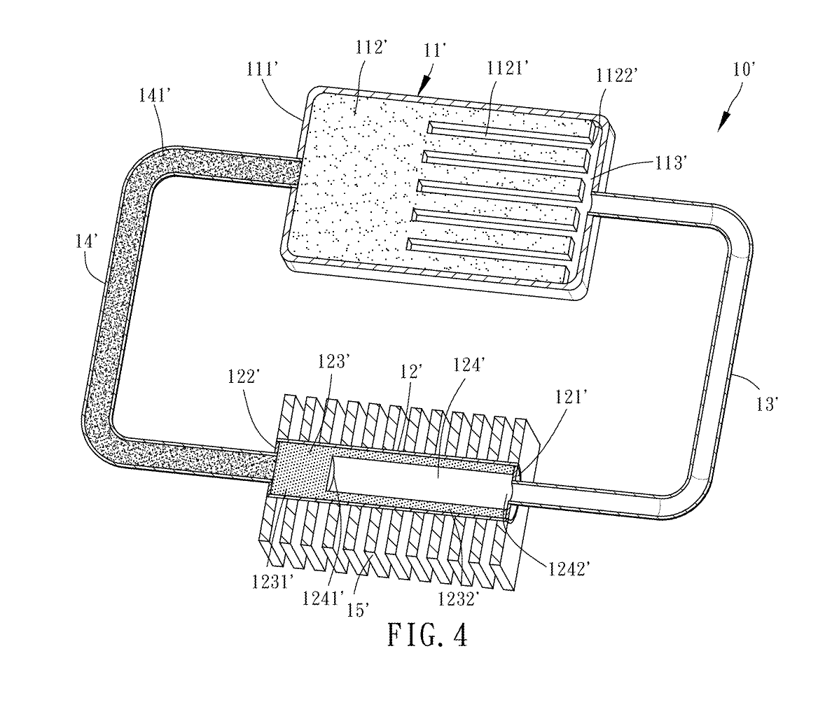

Referring to FIG. 4 through FIG. 6, the second preferred embodiment of the present disclosure provides a loop heat pipe 10′ having a condensation segment partially filled with a wick. The second preferred embodiment is substantially identical to the first preferred embodiment except for the distinguishing technical features described below.

The second wick 123′ is substantially cylindrical. The second wick 123′ has a bottom 1231′ which adjoins a liquid connection end 122′ of the condensation segment 12′. The second wick 123′ has a body 1232′. The body 1232′ has a round sectional outline and extends from the rim of the bottom 1231′, across the inner wall of the condensation segment 12′, and to the vapor connection end 121′ of the condensation segment 12′. The second wick 123′ is disposed in the condensation segment 12′ so as to form the second space 124′. The second space 124′, which is slender and has a round cross section, has a closed end 1241′ and an open end 1242′. The closed end 1241′ is adjacent to the second wick 123′. The open end 1242′ corresponds in position to the vapor connection end 121′ and the vapor delivery pipe 13′. Therefore, the second wick 123′ disposed circumferentially on the inner wall of the condensation segment 12′ enables the gaseous working fluid to remove heat away from the condensation segment 12′ uniformly and quickly such that the gaseous working fluid and the heat-dissipating unit 15′ can jointly dissipate heat and perform a cooling function. In addition, under a capillary force provided by the second wick 123′, the liquid working fluid resulting from condensation can flow to the liquid delivery pipe 14′ quickly and smoothly.

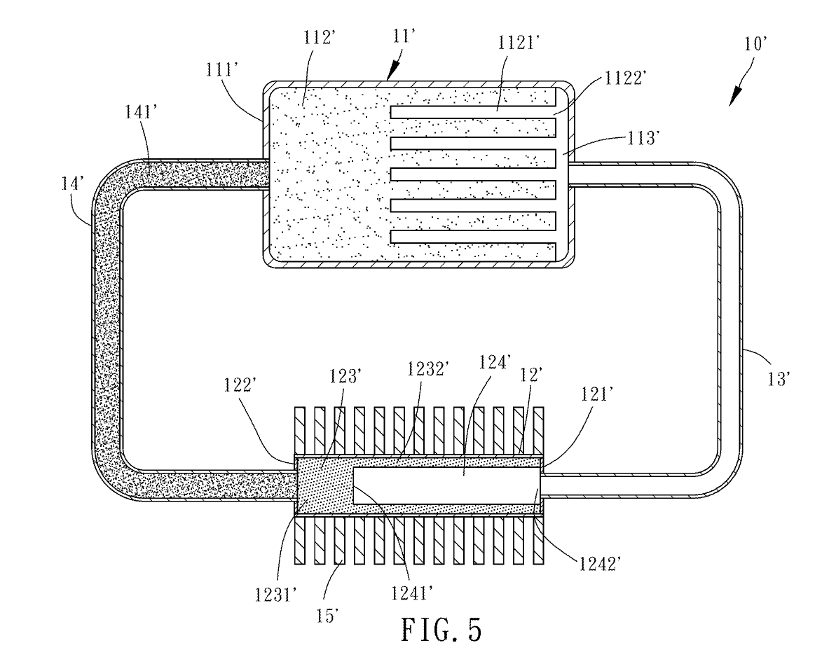

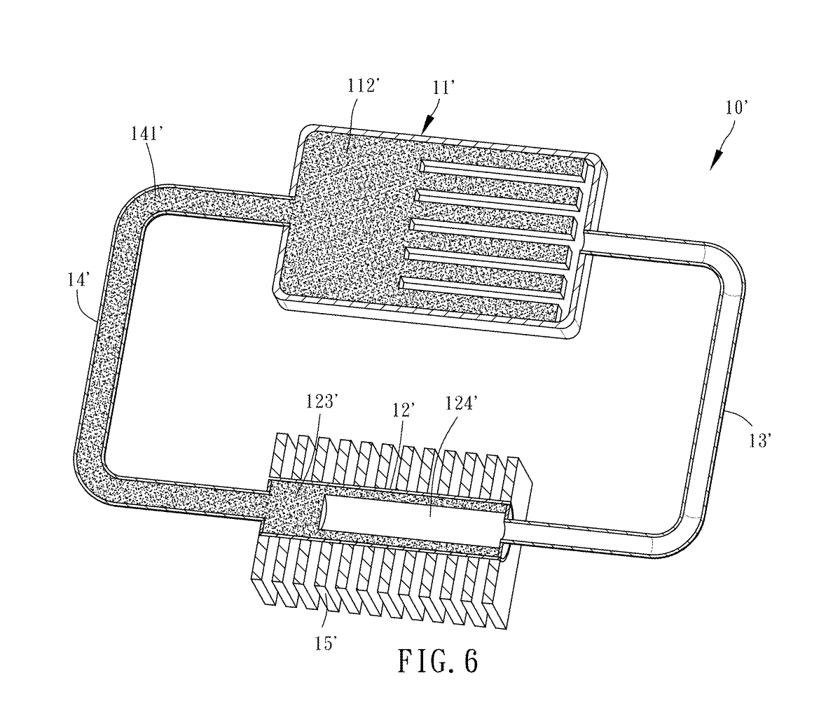

As shown in FIG. 4 and FIG. 5, the first wick 112′, the second wick 123′ and the third wick 141′ are separate, self-contained capillary structures placed in the casing 111′, the condensation segment 12′ and the liquid delivery pipe 14′, respectively. Alternatively, as shown in FIG. 6, the first wick 112′, the second wick 123′ and the third wick 141′ are integrally formed by sintering and simultaneously placed in the casing 111′, the condensation segment 12′ and the liquid delivery pipe 14′.

The other structural features and achievable advantages of the second preferred embodiment are substantially identical to those of the first preferred embodiment and thus, for the sake of brevity, are not described herein.

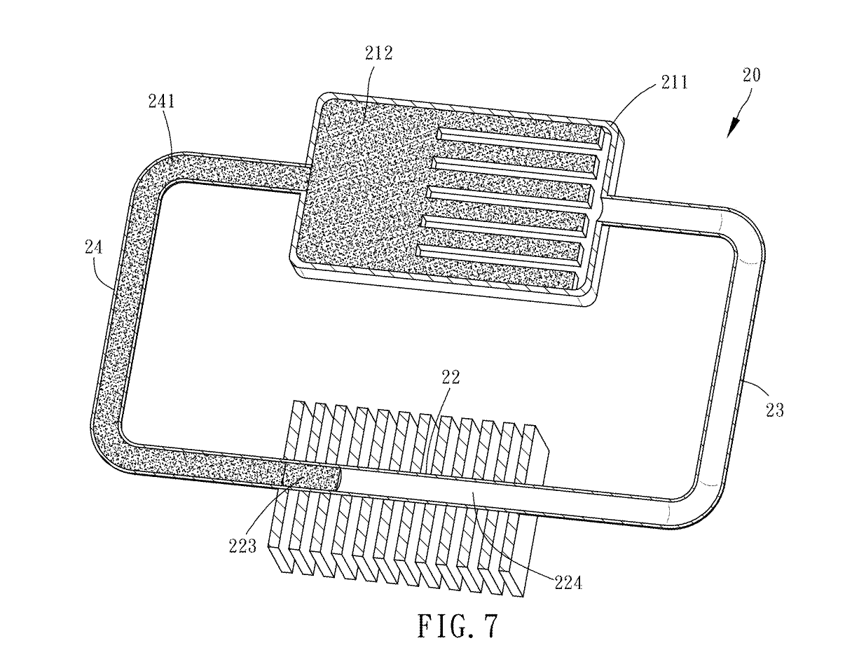

Referring to FIG. 7, the third preferred embodiment of the present disclosure provides a loop heat pipe 20 having a condensation segment partially filled with a wick. The third preferred embodiment is substantially identical to the first preferred embodiment except for the distinguishing technical features described below.

The vapor delivery pipe 23 has the same diameter as the liquid delivery pipe 24. The vapor delivery pipe 23 and the liquid delivery pipe 24 connect to the condensation segment 22. The liquid delivery pipe 24 is filled with a third wick 241. The third wick 241 is in contact with the first wick 212 in the casing 211 and the second wick 223 in the condensation segment 22. The second wick 223 looks like a short post.

The first wick 212, the second wick 223 and the third wick 241 are separate, self-contained capillary structures placed in the casing 211, the condensation segment 22 and the liquid delivery pipe 24, respectively. Alternatively, as shown in the diagrams which illustrate this embodiment, the first wick 212, the second wick 223 and the third wick 241 are integrally formed by sintering and simultaneously placed in the casing 211, the condensation segment 22 and the liquid delivery pipe 24.

The other structural features and achievable advantages of the third preferred embodiment are substantially identical to those of the first preferred embodiment and thus, for the sake of brevity, are not described herein.

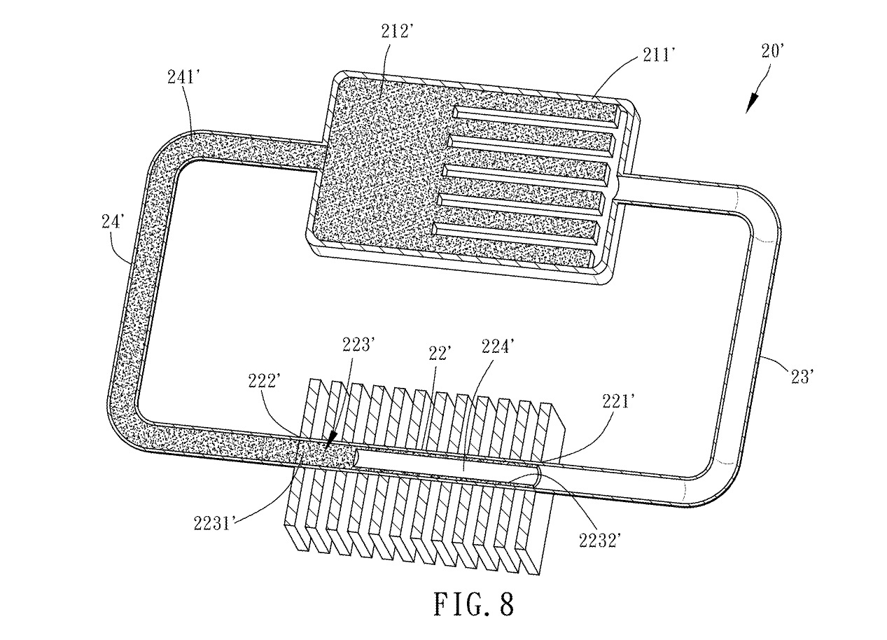

Referring to FIG. 8, the fourth preferred embodiment of the present disclosure provides a loop heat pipe 20′ having a condensation segment partially filled with a wick. The fourth preferred embodiment is substantially identical to the first preferred embodiment except for the distinguishing technical features described below.

The vapor delivery pipe 23′ has the same diameter as the liquid delivery pipe 24′. The vapor delivery pipe 23′ and the liquid delivery pipe 24′ connect to the condensation segment 22′. The liquid delivery pipe 24′ is filled with a third wick 241′. The third wick 241′ is in contact with a first wick 212′ in a casing 211′ and a second wick 223′ in the condensation segment 22′. As shown in the diagrams which illustrate this embodiment, the second wick 223′ is substantially cylindrical. The second wick 223′ has a bottom 2231′ which adjoins a liquid connection end 222′ of the condensation segment 22′. The second wick 223′ has a body 2232′. The body 2232′ has a round sectional outline and extends from the rim of the bottom 2231′, across the inner wall of the condensation segment 22′, and to the vapor connection end 221′ of the condensation segment 22′.

The first wick 212′, the second wick 223′ and the third wick 241′ are separate, self-contained capillary structures placed in the casing 211′, the condensation segment 22′ and the liquid delivery pipe 24′. Alternatively, as shown in the diagrams which illustrate this embodiment, the first wick 212′, the second wick 223′ and the third wick 241′ are integrally formed by sintering and simultaneously placed in the casing 211′, the condensation segment 22′ and the liquid delivery pipe 24′.

The other structural features and achievable advantages of the fourth preferred embodiment are substantially identical to those of the first preferred embodiment and thus, for the sake of brevity, are not described herein.

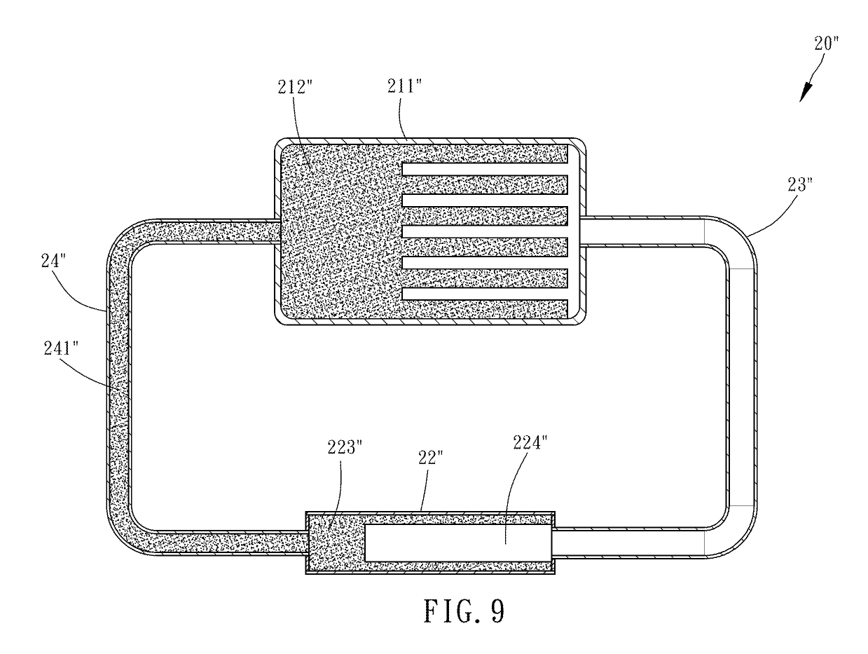

Referring to FIG. 9, the fifth preferred embodiment of the present disclosure provides a loop heat pipe 20″ having a condensation segment partially filled with a wick. The fifth preferred embodiment is substantially identical to the second preferred embodiment except for the distinguishing technical features described below.

The liquid delivery pipe 24″ is of a smaller inner diameter than the vapor delivery pipe 23″. The vapor delivery pipe 23″ and the liquid delivery pipe 24″ connect to the condensation segment 22″. The liquid delivery pipe 24″ is filled with a third wick 241″. The third wick 241″ is in contact with the first wick 212″ in the casing 211″ and the second wick 223″ in the condensation segment 22″.

The other structural features and achievable advantages of the fifth preferred embodiment are substantially identical to those of the second preferred embodiment and thus, for the sake of brevity, are not described herein.

Therefore, advantages achieved by the loop heat pipes 10, 10′, 20, 20′, 20″ of the present disclosure are as follows: the condensation segments 12, 12′, 22, 22′, 22″ have therein the second wicks 123, 123′, 223, 223′, 223″ and the second spaces 124, 124′, 224, 224′, 224″, whereas the liquid delivery pipes 14, 14′, 24, 24′, 24″ have therein the third wicks 141, 141′, 241, 241′, 241″, so as to enhance the heat dissipation efficiency of the loop heat pipes 10, 10′, 20, 20′, 20″.

What is claimed is:

1. A loop heat pipe having a condensation segment partially filled with a wick, comprising:
an evaporation chamber having a casing and a first wick disposed in the casing, the casing being not fully filled with the first wick such that a first space is formed between the casing and the first wick;
a condensation segment being a hollow-cored tube, the hollow-cored tube having a vapor connection end and a liquid connection end in communication with the vapor connection end, the tube being externally provided with a heat-dissipating unit, the tube being partially filled with a second wick to form a second space in the tube, the second wick being disposed at the liquid connection end of the tube, wherein the second space has an end adjoining the second wick and another end being in communication with the vapor connection end;
a vapor delivery pipe having an end not only connecting to the casing but also being in communication with the first space and another end not only connecting to the vapor connection end of the condensation segment but also being in communication with the second space; and
a liquid delivery pipe having an end not only connecting to the casing but also being in communication with the casing and another end not only connecting to the liquid connection end of the condensation segment but also being in communication with the condensation segment, wherein the liquid delivery pipe is filled with a third wick, the third wick being in contact with the first wick and the second wick.

2. The loop heat pipe having a condensation segment partially filled with a wick in accordance with claim 1, wherein the liquid delivery pipe is of a larger inner diameter than the vapor delivery pipe.

3. The loop heat pipe having a condensation segment partially filled with a wick in accordance with claim 1, wherein the liquid delivery pipe is of a smaller inner diameter than the vapor delivery pipe.

4. The loop heat pipe having a condensation segment partially filled with a wick in accordance with claim 2, wherein the liquid delivery pipe is of a smaller inner diameter than the condensation segment.

5. The loop heat pipe having a condensation segment partially filled with a wick in accordance with claim 1, wherein the second wick is substantially cylindrical, has a bottom adjoining the liquid connection end of the condensation segment, and has a body, the body having a round sectional outline and extending from a rim of the bottom, across an inner wall of the condensation segment, and to the vapor connection end of the condensation segment, the second wick being disposed in the condensation segment so as to form the second space, wherein the second space, which is slender and has a round cross section, has a closed end and an open end, the closed end being adjacent to the second wick, and the open end corresponding in position to the vapor connection end and the vapor delivery pipe.

6. The loop heat pipe having a condensation segment partially filled with a wick in accordance with claim 1, wherein the first wick, the second wick and the third wick are integrally formed by sintering.

7. The loop heat pipe having a condensation segment partially filled with a wick in accordance with claim 1, wherein the first wick, the second wick and the third wick are each a capillary structure made from sintered powder, mesh or fiber.
